(19) United States
(12) Patent Application Publication
(10) Pub. No.: US 2008/0035994 A1
(43) Pub. Date: Feb. 14, 2008

(54) Semiconductor Device and Method of Manufacturing the Same

(76) Inventor: Duck Ki Jang, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/782,820

(22) Filed: Jul. 25, 2007

(30) Foreign Application Priority Data
Aug. 11, 2006 (KR) 10-2006-0076087

(51) Int. Cl. H01L 29/78; H01L 21/336

(52) U.S. Cl. 257/339; 438/289; 257/E29.256; 257/E21.417

(57) ABSTRACT

A semiconductor device and a method of manufacturing the same are provided, capable of minimizing a size of the semiconductor device and inhibiting punch through. According to an embodiment, at least one conductive bar is formed in a substrate between source and drain regions. Thereby, punch through can be inhibited to the utmost to increase breakdown voltage, and thus the electrical properties of the device can be improved. Further, because the punch through is inhibited, the size of the device can be minimized without degrading the electrical properties of the device.

### CROSS-REFERENCE TO RELATED APPLICATION

The present application claims the benefit under 35 U.S.C. §119 of Korean Patent Application No. 10-2006-0076087, filed Aug. 11, 2006, which is hereby incorporated by reference in its entirety.

### BACKGROUND

With the increasing integration density of semiconductor devices, and with the development of the resulting design technologies, an attempt is being made to establish a system in a single semiconductor chip. This establishment of a system into a single chip is developed into technology for integrating controllers, memories, and other circuits operating at a low voltage, all of which take charge of main functions of the system, into the single chip.

However, in order to make the system lighter and smaller, a circuit that performs main functions of input and output terminals controlling power of the system must be integrated into the single chip. The technology making this possible is a power integrated circuit (IC) technology that integrates a high-voltage transistor and a low-voltage complementary metal oxide semiconductor (CMOS) transistor into a single chip.

In general, the high-voltage transistor comprises a gate, a channel below the gate, and high-concentration n-type source and drain regions on both sides of the channel. Further, the high-voltage transistor can include a low-concentration n-type drift region, which maintains a predetermined distance from a boundary of the high-concentration n-type drain region in order to disperse an electric field applied to the high-concentration n-type drain region when the device is driven, and surrounds the high-concentration n-type drain region.

Meanwhile, a recent study has been made of a lateral diffused MOS (LDMOS) transistor, which not only disposes the high-concentration n-type drain region in a horizontal direction in order to secure high breakdown voltage, but also disposes the low-concentration n-type drift region that surrounds the high-concentration n-type drain region at a predetermined distance from the high-concentration n-type drain region in a horizontal direction.

The device can be decreased in size to a certain extent by the LDMOS transistor, but is limited to reducing the size thereof. In other words, when the size of the device is reduced, the length of a channel is also reduced. In this manner, when the channel length is reduced, punch through easily occurs. This lowers the breakdown voltage of the device, which degrades characteristics of the device, thereby making it difficult to be applied to the high-voltage device and also lowers reliability of the device.

### BRIEF SUMMARY

Accordingly, embodiments of the present invention are directed to a semiconductor device, capable of minimizing a size thereof, and a method of manufacturing the same that addresses or substantially obviates one or more of the problems, limitations, and/or disadvantages of the related art.

One embodiment provides a semiconductor device, capable of inhibiting punch through to improve properties thereof, and a method of manufacturing the same.

According to an embodiment, a method of manufacturing a semiconductor device can include: forming a well region of a first conductive type in a substrate; forming a first drift region of a second conductive type in source and drain regions of the substrate; forming a second drift region of the first conductive type and at least one first conductive type bar; forming a poly gate on the substrate between the source and drain regions; forming a first impurity region of the second conductive type in the first drift region; and forming a second impurity region of the first conductive type in the second drift region.

According to an embodiment, a semiconductor device can include: a well region of a first conductive type formed in a substrate; a first drift region of a second conductive type formed in source and drain regions of the substrate; a second drift region of the first conductive type formed so as to surround the first drift region; at least one bar formed between the first and second drift regions; a poly gate formed on the substrate between the source and drain regions; a first impurity region of the second conductive type formed in the first drift region; and a second impurity region of the first conductive type formed in the second drift region.

### BRIEF DESCRIPTION OF THE DRAWINGS

FIGS. 1A and 1B are a cross-sectional view and a plan view illustrating a structure of a lateral diffused metal oxide semiconductor (LDMOS) transistor according to an embodiment; and

FIGS. 2A through 2F are views illustrating a method of manufacturing an LDMOS transistor according to an embodiment.

### DETAILED DESCRIPTION OF THE EMBODIMENTS

Hereinafter, a semiconductor device and method of manufacturing the same according to embodiments of the present invention will be described in detail with reference to the accompanying drawings.

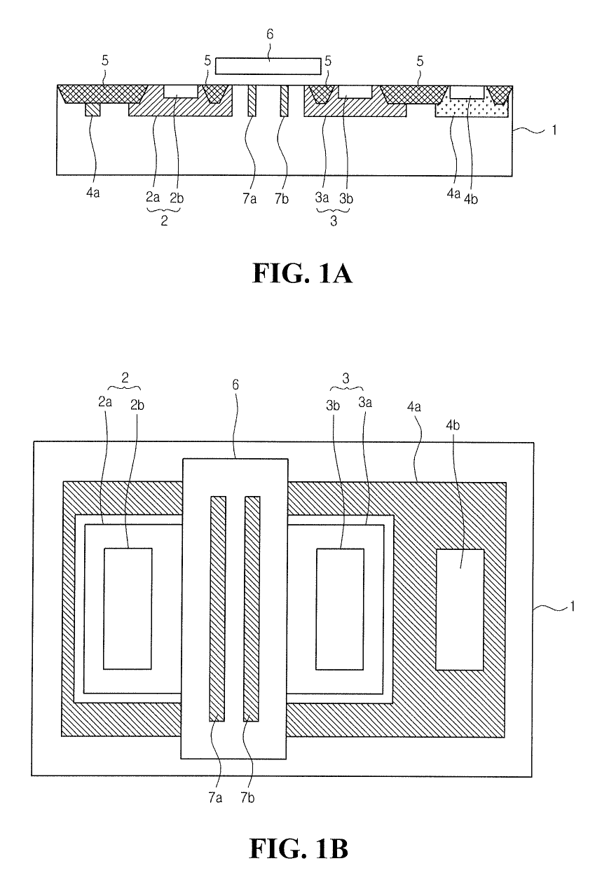

FIGS. 1A and 1B are a cross-sectional view and a plan view, respectively, illustrating a structure of a lateral diffused metal oxide semiconductor (LDMOS) transistor according to an embodiment.

In FIGS. 1A and 1B, an n-type MOS transistor is illustrated for the convenience of description.

Referring to FIGS. 1A and 1B, low-concentration p-type impurities can be implanted into a substrate 1, thereby forming a p-type well region (not shown). N-type impurities are implanted at a low concentration into source and drain regions 2 and 3 of the substrate 1 having the p-type well region to form n-type drift regions 2a and 3a. Here, the n-type drift regions 2a and 3a are spaced apart from each other by a predetermined distance.

High-concentration n-type impurities can be implanted into the n-type drift regions 2a and 3a to form n-type impurity regions 2b and 3b. The concentration of the n-type impurity regions 2b and 3b is relatively higher than that of the n-type drift regions 2a and 3a.

When the device is in operation, the n-type drift regions 2a and 3a inhibit an electric field from being concentrated on the n-type impurity regions 2b and 3b, thereby dispersing the electric field. In particular, the electric field concentrated on the n-type impurity regions 2b and 3b is dispersed to the n-type drift regions 2a and 3a so that electrical properties of the semiconductor device can be inhibited from being degraded.

P-type impurities can be implanted so as to surround the n-type drift regions 2a and 3a of the source and drain regions 2 and 3 to form a p-type drift region 4a. Part of the p-type drift region 4a is further implanted with p-type impurities to form a p-type impurity region 4b. The p-type impurity region 4b is formed only at a portion of the p-type drift region 4a rather than the whole of the p-type drift region 4a. In operation, when a predetermined signal is supplied to the p-type impurity region 4b, the signal supplied to the p-type impurity region 4b is transmitted to the p-type drift region 4a. The p-type drift region 4a is formed for insulation between the devices. Particularly, in the case of high-voltage devices, high voltage is applied to each device, which may exert an influence on an adjacent device. In order to help avoid this influence, the p-type impurity region 4b and the p-type drift region 4a are formed. When supplied to the p-type impurity region 4b, the predetermined signal is transmitted throughout the p-type drift region 4a. As a result, the signal is supplied to the entire p-type drift region 4a. Accordingly, the signal supplied to the p-type drift region 4a, particularly to an n-type metal oxide semiconductor (NMOS) transistor in the p-type drift region 4a, exerts no (or insignificant) influence on an adjacent p-type MOS transistor (not shown).

Meanwhile, at least one bar is formed between the source and drain regions 2 and 3 of the substrate 1. In a preferred embodiment, two bars 7a and 7b are formed between the source and drain regions 2 and 3 of the substrate 1. The bars 7a and 7b can increase the length of a channel between the source and drain to the maximum extent, thereby inhibiting the generation of punch through to the utmost, and increasing breakdown voltage. Consequently, the electrical properties of the device can be improved.

The bars 7a and 7b can be formed at the same time as the p-type drift region 4a is formed. The bars 7a and 7b can be formed using the p-type impurities like the p-type drift region 4a. Each of the bars 7a and 7b has an angled shape or a rounded shape at the bottom thereof. The bar can be singular or plural in number. Preferably, the number of bars has a range of two to five.

Even in the case in which the number of bars is one or exceeds five, the punch through can be inhibited to increase the electrical properties of the device, but a current reverse phenomenon may take place. For this reason, the number of bars preferably has a range of two to five.

A poly gate 6 can be formed on the substrate 1 between the source and drain regions 2 and 3. At this time, the poly gate 6 can partly overlap with the n-type drift regions 2a and 3a.

In order to isolate between adjacent devices, shallow trench isolation (STI) regions 5 are formed. The STI regions 5 can also be formed between the n-type impurity region 2b and the poly gate 6 and between the n-type impurity region 3b and the poly gate 6.

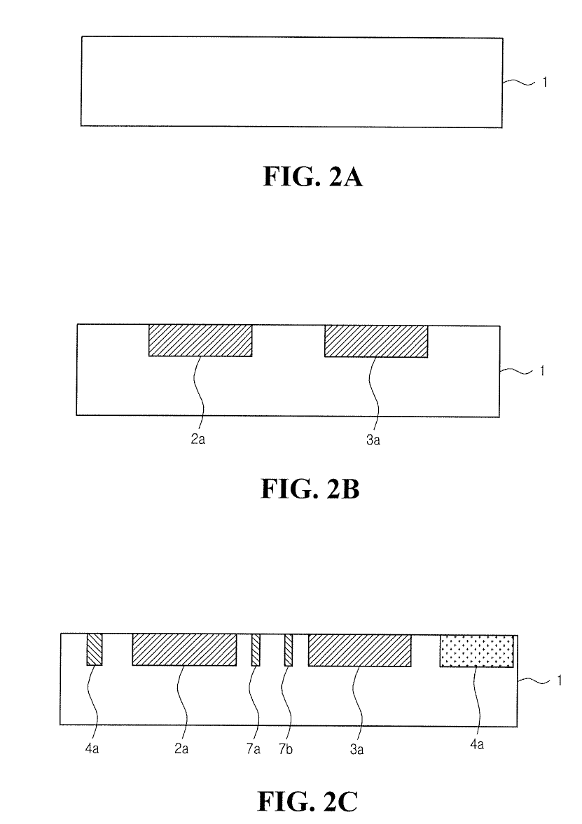

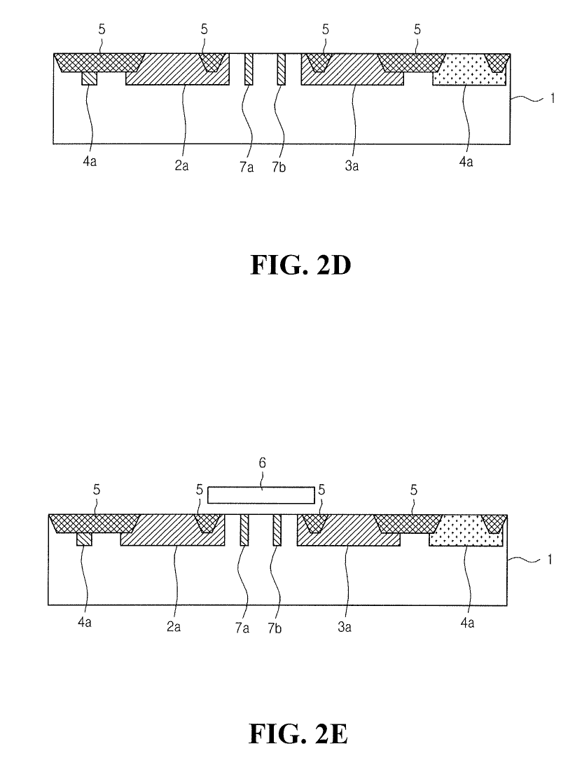

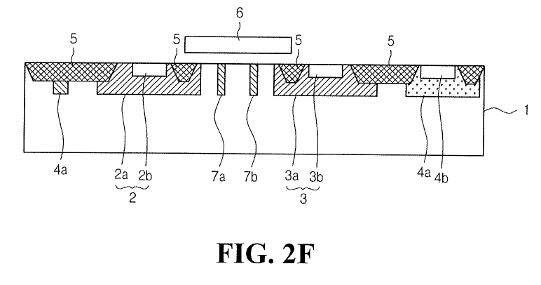

FIGS. 2A through 2F are views illustrating a method of manufacturing an LDMOS transistor according to an embodiment.

Referring to FIG. 2A, a substrate 1 can be provided. Low-concentration p-type impurities can be implanted into the substrate 1 by an implantation process to form a p-type well region (not shown). Although not illustrated in FIG. 2A, n-type impurities can also be implanted into an adjacent device region to form an n-type well region. Thus, the device regions can be formed into the n-type and p-type well regions, respectively.

The p-type well region can be expanded through diffusion by a drive-in process. The p-type well region can be mainly formed at a lower region of the substrate 1.

Referring to FIG. 2B, low-concentration n-type impurities can be implanted into source and drain regions of the substrate 1 having the p-type well region through an implantation process to form n-type drift regions 2a and 3a. Subsequently, the n-type drift regions 2a and 3a can be expanded through diffusion by a drive-in process. In one embodiment, the n-type drift regions 2a and 3a can be intensively diffused in a horizontal direction. The MOS transistor having this structure is an LDMOS transistor. The n-type drift regions 2a and 3a of the source and drain regions are spaced apart from each other by a predetermined distance, which establishes a channel length.

Referring to FIG. 2C, low-concentration p-type impurities can be implanted around the n-type drift regions 2a and 3a of the source and drain regions by an implantation process to form a p-type drift region 4a.

The p-type drift region 4a surrounds the n-type drift regions 2a and 3a of the source and drain regions, thereby inhibiting an electrical signal of the n-type MOS transistor from influencing an adjacent MOS transistor when the device is in operation.

In addition, p-type impurities are implanted into the substrate between the source and drain regions by an implantation process to form at least one bar, for example, two bars 7a and 7b. The bars 7a and 7b have a bar shape extending in a lengthwise direction. Each of the bars 7a and 7b can have an angled shape or a rounded shape at the bottom thereof. The interval between the bars 7a and 7b and the depth of each of the bars 7a and 7b can be optimized through testing.

In an embodiment, at least one bar (7a,7b) is formed in the substrate between the source and drain regions, so that the channel length is increased to inhibit the punch through. Further, the breakdown voltage is increased, which improves the electrical properties of the device.

The number of bars may be singular or plural. Most preferably, the number of bars has a range of two to five.

In the case in which the number of bars is one or exceeds five, there is a possibility of giving rise to a reverse current phenomenon.

Referring to FIG. 2D, shallow trench isolation regions 5 can be formed at the sides of the n-type impurity regions 2b and 3b (which will be subsequently formed) in the n-type drift regions 2a and 3a, between the n-type drift regions 2a and 3a and the p-type drift region 4a, and between adjacent MOS transistors.

Referring to FIG. 2E, a poly gate 6 is formed on the substrate 1 between the source and drain regions including an oxide layer (not shown). The poly gate 6 can partly overlap with the n-type drift regions 2a and 3a. Although not illustrated, spacers can be formed on sidewalls of the poly gate 6.

Referring to FIG. 2F, high-concentration n-type impurities can be implanted into the n-type drift regions 2a and 3a using the poly gate 6 and the spacers (if included) as masks through an implantation process to form n-type impurity regions 2b and 3b. In other words, the n-type impurity region 2b is formed in the n-type drift region 2a of the source region, and the n-type impurity region 3b is formed in the n-type drift region 3a of the drain region.

Accordingly, both the n-type impurity region 2b and the n-type drift region 2a, which surrounds the n-type impurity region 2b, are formed in the source region 2, and both the n-type impurity region 3b and the n-type drift region 3a, which surrounds the n-type impurity region 3b, are formed in the drain region 3.

In a further embodiment, high-concentration p-type impurities can be implanted into the p-type drift region 4a through an implantation process to form a p-type impurity region 4b. The p-type impurity region 4b is formed so as to partly overlap with the p-type drift region 4a. Thus, when an electrical signal transmitted through the p-type impurity region 4b is applied to the p-type drift region 4a, an electrical signal of the n-type MOS transistor is inhibited from influencing an adjacent MOS transistor when the device is in operation.

As can be seen from the above description, according to embodiments of the present invention, at least one bar is formed in the channel region, so that the breakdown voltage of the device can be increased, and thus the size of the device can be reduced to the utmost.

According to embodiments, at least one bar is formed in the channel region, so that the punch through is inhibited to the utmost to increase the breakdown voltage of the device, and thereby improve the electrical properties of the device.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method of manufacturing a semiconductor device, the method comprising:
forming a well region of a first conductive type in a substrate;
forming a first drift region of a second conductive type in source and drain regions of the substrate;
forming a second drift region of the first conductive type;
forming at least one bar of the first conductive type in the substrate;
forming a poly gate on the substrate between the source and drain regions;
forming a first impurity region of the second conductive type in the first drift region; and
forming a second impurity region of the first conductive type in the second drift region.

2. The method according to claim 1, wherein the at least one bar is formed between the first and second drift regions.

3. The method according to claim 2, wherein the at least one bar is formed in the substrate under the poly gate.

4. The method according to claim 1, wherein the at least one bar has an angled shape or a rounded shape at a bottom thereof.

5. The method according to claim 1, wherein the at least one bar is singular in number.

6. The method according to claim 1, wherein the at least one bar is in the range of two to five in number.

7. The method according to claim 1, wherein the second drift region is formed in the substrate so as to peripherally surround the first drift region.

8. A semiconductor device comprising:
a well region of a first conductive type formed in a substrate;
a first drift region of a second conductive type formed in source and drain regions of the substrate;
a second drift region of the first conductive type formed peripherally surrounding the first drift region;
at least one bar formed between the first and second drift regions;
a poly gate formed on the substrate between the source and drain regions;
a first impurity region of the second conductive type formed in the first drift region; and
a second impurity region of the first conductive type formed in the second drift region.

9. The semiconductor device according to claim 8, wherein the at least one bar is formed of the first conductive type.

10. The semiconductor device according to claim 8, wherein the at least one bar has an angled shape or a rounded shape at a bottom thereof.

11. The semiconductor device according to claim 8, wherein the at least one bar is formed in the substrate under the poly gate.

12. The semiconductor device according to claim 8, wherein the at least one bar is formed between the first and second drift regions in a bar shape in a lengthwise direction.

13. The semiconductor device according to claim 8, wherein the at least one bar is singular in number.

14. The semiconductor device according to claim 8, wherein the at least one bar is in the range of two to five in number.
